(19) United States
(12) Patent Application Publication
(10) Pub. No.: US 2026/0103801 A1
(43) Pub. Date: Apr. 16, 2026

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: KOKUSAI ELECTRIC CORPORATION, Tokyo (JP)

(72) Inventor: Tomoya NAGAHASHI, Toyama-shi (JP)

(73) Assignee: KOKUSAI ELECTRIC CORPORATION, Tokyo (JP)

(21) Appl. No.: 19/330,665

(22) Filed: Sep. 16, 2025

(30) Foreign Application Priority Data
Oct. 16, 2024 (JP) 2024-180700

(51) Int. Cl. C23C 16/455; C23C 16/44

(52) U.S. Cl. CPC C23C 16/45557; C23C 16/4412; C23C 16/45523

(57) ABSTRACT

There is provided a technique that includes: forming a film on a substrate by performing a cycle a predetermined number of times, the cycle including: (a) supplying a first reactant which reacts with a surface of the substrate to the substrate at a first partial pressure; and (b) after (a), exhausting a process space in which the substrate is processed such that a partial pressure of a reaction product, which is generated by a reaction between the surface of the substrate and the first reactant and present in the process space, becomes a second partial pressure, wherein (a) and (b) are performed such that the first partial pressure and the second partial pressure are set, respectively, to make a ratio of the second partial pressure to the first partial pressure be equal to or less than a predetermined partial pressure ratio.

### CROSS-REFERENCE TO RELATED APPLICATION

This application is based upon and claims the benefit of priority from Japanese Patent Application No. 2024-180700, filed on Oct. 16, 2024, the entire contents of which are incorporated herein by reference.

### TECHNICAL FIELD

The present disclosure relates to a method of processing a substrate, a method of manufacturing a semiconductor device, a recording medium, and a substrate processing apparatus.

### BACKGROUND

In the related art, as a process of manufacturing a semiconductor device, a film such as a nitride film may be formed on a surface of a substrate by performing a cycle including supplying a reactant such as a nitrogen-containing gas to the substrate.

### SUMMARY

The present disclosure provides a technique capable of improving a film formation efficiency in a film formation step including supplying a reactant to a substrate.

According to some embodiments of the present disclosure, there is provided a technique that includes: forming a film on a substrate by performing a cycle a predetermined number of times, the cycle including: (a) supplying a first reactant which reacts with a surface of the substrate to the substrate at a first partial pressure; and (b) after (a), exhausting a process space in which the substrate is processed such that a partial pressure of a reaction product, which is generated by a reaction between the surface of the substrate and the first reactant and present in the process space, becomes a second partial pressure, wherein when (a) and (b) are performed such that the first partial pressure and the second partial pressure are set, respectively, to make a ratio of the second partial pressure to the first partial pressure be equal to or less than a predetermined partial pressure ratio.

### BRIEF DESCRIPTION OF DRAWINGS

The accompanying drawings, which are incorporated in and constitute a part of the specification, illustrate embodiments of the present disclosure.

FIG. 1 is a schematic configuration view of a vertical process furnace of a substrate processing apparatus suitably used in some embodiments of the present disclosure, in which a portion of the process furnace is shown in a vertical cross section.

FIG. 2 is a schematic configuration diagram of a vertical process furnace of a substrate processing apparatus suitably used in some embodiments of the present disclosure, in which a portion of the process furnace is illustrated in a cross-sectional view taken along line A-A of FIG. 1.

FIG. 3 is a schematic configuration diagram of a controller of the substrate processing apparatus suitably used in some embodiments of the present disclosure, in which a control system of the controller is illustrated in a block diagram.

FIG. 4 is a diagram illustrating a substrate processing step in some embodiments of the present disclosure.

FIGS. 5A and 5B are diagrams illustrating a reaction on a substrate generated by supplying a reaction gas.

FIG. 6 is a schematic configuration diagram of a vertical process furnace of a substrate processing apparatus according to other embodiments of the present disclosure, in which a portion of the process furnace is shown in a vertical cross section.

FIG. 7 is a diagram illustrating a substrate processing step according to other embodiments of the present disclosure.

### DETAILED DESCRIPTION

### Embodiments of Present Disclosure

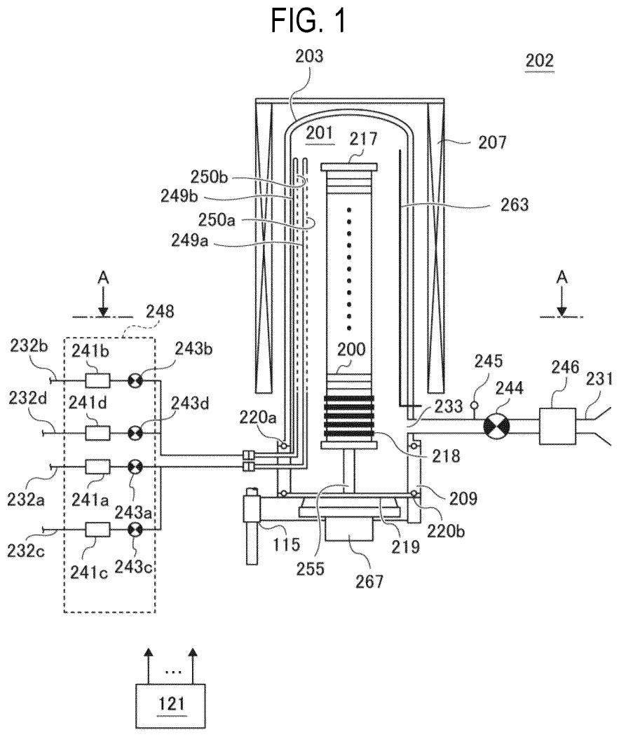

Hereinafter, some embodiments of the present disclosure will be described mainly with reference to FIGS. 1 to 5B. In addition, drawings used in the following description are schematic, and dimensional relationships, ratios, and the like of various components illustrated in the drawings may not match actual ones. Further, dimensional relationships, ratios, and the like of various components among plural drawings may not match one another.

### (1) Configuration of Substrate Processing Apparatus

As illustrated in FIG. 1, a process furnace 202 includes a heater 207 as a heating system (temperature regulator). The heater 207 is formed in a cylindrical shape and is supported by a holding plate so as to be vertically installed. The heater 207 also functions as an activator (an exciter) configured to thermally activate (excite) gases.

A reaction tube 203 is disposed inside the heater 207 to be concentric with the heater 207. The reaction tube 203 is made of, for example, a heat resistant material such as quartz (SiO₂) and formed in a cylindrical shape with its upper end closed and its lower end opened. A manifold 209 is disposed to be concentric with the reaction tube 203 under the reaction tube 203. An upper end of the manifold 209 engages with the lower end of the reaction tube 203 so as to support the reaction tube 203. An O-ring 220a serving as a seal is installed between the manifold 209 and the reaction tube 203. A process container (reaction container) mainly includes the reaction tube 203 and the manifold 209. A process chamber 201 as a process space is formed in a hollow cylindrical area of the process container. The process chamber 201 is configured to be capable of accommodating wafers 200 as substrates. The wafers 200 are processed in the process chamber 201.

Nozzles 249a and 249b are installed in the process chamber 201 so as to penetrate a sidewall of the manifold 209. Gas supply pipes (piping) 232a and 232b are connected to the nozzles 249a and 249b respectively.

Mass flow controllers (MFCs) 241a and 241b, which serve as flow rate controllers (flow rate control parts), and valves 243a and 243b, which serve as opening/closing valves, are installed at the gas supply pipes 232a and 232b, respectively, sequentially from the upstream side. Gas supply pipes 232c and 232d configured to supply an inert gas are connected to the gas supply pipes 232a and 232b at the downstream sides of the valves 243a and 243b, respectively. MFCs 241c and 241d and valves 243c and 243d are installed at the gas supply pipes 232c and 232d, respectively, sequentially from the upstream side.

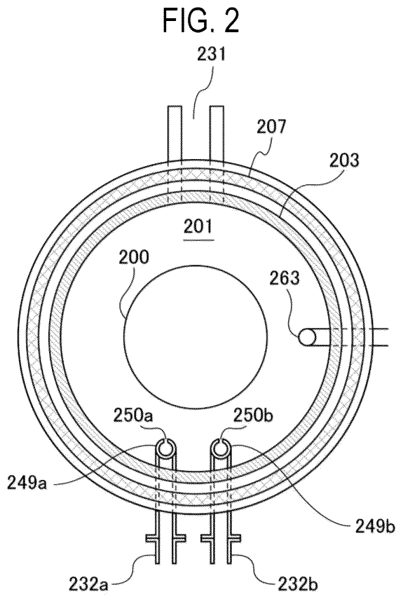

As illustrated in FIG. 2, the nozzles 249a and 249b are respectively installed in an annular space (in a plan view) between an inner wall of the reaction tube 203 and the wafers 200 so as to extend upward in an arrangement direction of the wafers 200 from a lower side to an upper side of the inner wall of the reaction tube 203. Gas supply holes 250a and 250b, which are supply ports configured to supply gases, are respectively formed at side surfaces of the nozzles 249a and 249b. A plurality of gas supply holes 250a and 250b are formed from the lower side to the upper side of the reaction tube 203.

A precursor gas containing a predetermined element is supplied from the gas supply pipe 232a into the process chamber 201 via the MFC 241a, valve 243a, and nozzle 249a.

A reaction gas serving as a first reactant which reacts with the precursor gas is supplied from the gas supply pipe 232b into the process chamber 201 via the MFC 241b, valve 243b, and nozzle 249b.

In the present disclosure, the precursor gas may also be referred to as a second reactant which reacts with the first reactant.

An inert gas is supplied from the gas supply pipes 232c and 232d into the process chamber 201 via the MFCs 241c and 241d, valves 243c and 243d, gas supply pipes 232a and 232b, and nozzles 249a and 249b, respectively. The inert gas supplied from the gas supply pipes 232c and 232d is used as a dilution gas that dilutes the precursor gas or the reaction gas when supplied simultaneously with the precursor gas or the reaction gas.

A precursor gas supply system (also referred to as a “second reactant supply system”) is mainly constituted by the gas supply pipe 232a, MFC 241a, and valve 243a. A reaction gas supply system (also referred to as a “first reactant supply system”) is mainly constituted by the gas supply pipe 232b, MFC 241b, and valve 243b. The precursor gas supply system and the reaction gas supply system may be collectively referred to as a “gas supply system” (also referred to as a “reactant supply system”). Further, an inert gas supply system is mainly constituted by the gas supply pipes 232c and 232d, MFCs 241c and 241d, and valves 243c and 243d. The inert gas supply system may be included in the gas supply system.

One or the entirety of the various supply systems described above may be constituted as an integrated-type supply system 248 in which the valves 243a to 243d, MFCs 241a to 241d, and so on are integrated. The integrated-type supply system 248 is connected to each of the gas supply pipes 232a to 232d, and is configured such that operations of supplying various gases into the gas supply pipes 232a to 232d (that is, opening/closing operations of the valves 243a to 243d, flow rate regulation operations by the MFCs 241a to 241h, and the like) are controlled by a controller 121 which will be described later. The integrated-type supply system 248 is constituted as an integral-type or detachable-type integrated unit, and may be attached to or detached from the gas supply pipes 232a to 232d and the like on an integrated unit basis, such that maintenance, replacement, extension, etc. of the integrated-type supply system 248 may be performed on an integrated unit basis.

The reaction tube 203 is provided with an exhaust pipe 231 configured to exhaust an internal atmosphere of the process chamber 201. A vacuum pump 246 as a vacuum exhauster, is connected to the exhaust pipe 231 via a pressure sensor 245, which is a pressure detector (pressure detection part) configured to detect an internal pressure of the process chamber 201, and an auto pressure controller (APC) valve 244, which is a pressure regulator (pressure regulation part). The APC valve 244 is configured to be capable of performing or stopping a vacuum exhaust operation in the process chamber 201 by opening or closing the valve while the vacuum pump 246 is actuated, and is also configured to be capable of regulating the internal pressure of the process chamber 201 by adjusting a degree of valve opening based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219, which serves as a furnace opening lid configured to be capable of hermetically sealing a lower end opening of the manifold 209, is installed under the manifold 209. An O-ring 220b, which is a seal making contact with the lower end of the manifold 209, is installed on an upper surface of the seal cap 219. A rotator 267 configured to rotate a boat 217 described below, is installed under the seal cap 219. A rotary shaft 255 of the rotator 267 is connected to the boat 217 through the seal cap 219. The rotator 267 is configured to rotate the wafers 200 by rotating the boat 217. The seal cap 219 is configured to be vertically moved up or down by a boat elevator 115 which is an elevator installed outside the reaction tube 203. The boat elevator 115 is configured to be capable of loading or unloading the boat 217 into or out of the process chamber 201 by moving the seal cap 219 up or down. The boat elevator 115 is constituted as a transfer apparatus (transfer mechanism) configured to transfer the boat 217, that is, wafers 200 into or out of the process chamber 201.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, heat resistant material such as quartz. Heat insulating plates 218 made of, for example, heat resistant material such as quartz are installed below the boat 217 in multiple stages.

A temperature sensor 263 serving as a temperature detector is installed in the reaction tube 203. Based on temperature information detected by the temperature sensor 263, a state of supplying electric power to the heater 207 is regulated such that a temperature distribution inside the process chamber 201 becomes a desired temperature distribution.

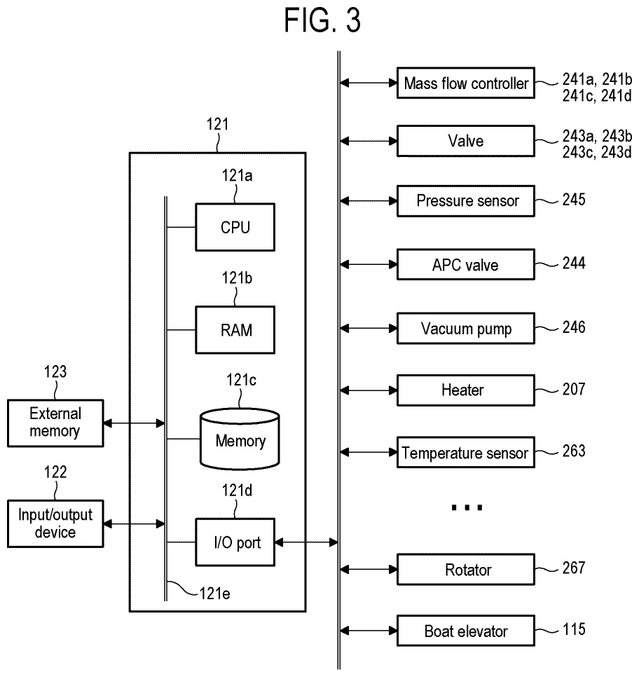

As shown in FIG. 3, a controller 121, which is a control part (control means or unit), is constituted as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 including, e.g., a touch panel or the like, is connected to the controller 121.

The memory 121c includes, for example, a flash memory, a hard disk drive (HDD), a solid state drive (SSD), or the like. A control program that controls operations of a substrate processing apparatus, a process recipe in which sequences and conditions of film formation described below are written, and the like are readably stored in the memory 121c. The process recipe functions as a program which is combined to cause the controller 121 to perform each sequence in the film formation described below, so as to obtain an expected result. Hereinafter, the process recipe and the control program may be generally and simply referred to as a “program (program product).” Furthermore, the process recipe may be simply referred to as a “recipe.” When the term “program” is used herein, it may indicate a case of including the recipe, a case of including the control program, or a case of including both the recipe and the control program. The RAM 121b is constituted as a memory area (work area) in which programs or data read by the CPU 121a are temporarily stored.

The I/O port 121d is connected to the aforementioned MFCs 241a to 241d, valves 243a to 243d, pressure sensor 245, APC valve 244, vacuum pump 246, heater 207, temperature sensor 263, rotator 267, boat elevator 115, and others.

The CPU 121a is configured to read and execute the control program from the memory 121c. The CPU 121a is also configured to be capable of reading the recipe from the memory 121c according to an input of an operation command from the input/output device 122. The CPU 121a is configured to be capable of controlling the flow rate regulating operation of various kinds of gases by the MFCs 241a to 241d, the opening/closing operation of the valves 243a to 243d, the opening/closing operation of the APC valve 244, the pressure regulating operation performed by the APC valve 244 based on the pressure sensor 245, the actuating and stopping operation of the vacuum pump 246, the temperature regulating operation performed by the heater 207 based on the temperature sensor 263, the operation of rotating the boat 217 with the rotator 267 and adjusting a rotation speed of the boat 217, the operation of moving the boat 217 up or down by the boat elevator 115, and so on, according to contents of the read recipe.

The controller 121 may be constituted by installing, on the computer, the above-described program recorded and stored in an external memory (e.g., a magnetic disk such as a hard disk, an optical disc such as a CD, and a semiconductor memory such as a USB memory) 123. The memory 121c or the external memory 123 is constituted as a computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Further, the program may be provided to the computer by using communication means or unit such as the Internet or a dedicated line, instead of using the external memory 123.

### (2) Substrate Processing Step

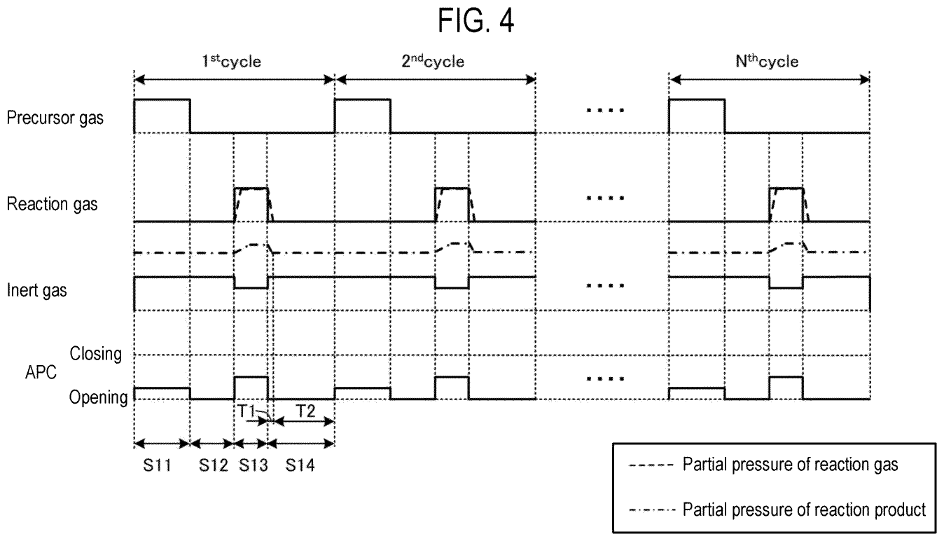

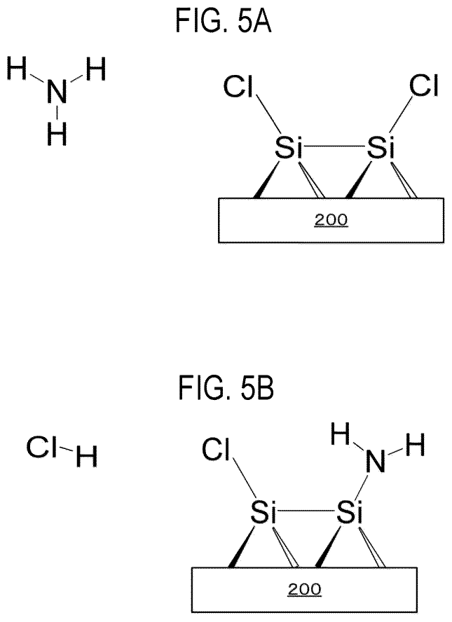

An example of a sequence to form a film containing a predetermined element on the wafer 200, as a substrate processing step in a process of manufacturing a semiconductor device by using the above-described substrate processing apparatus, will be described with reference to FIGS. 4 to 5B. In the following description, an operation of each component constituting the substrate processing apparatus is controlled by the controller 121.

When the term “wafer” is used in the present disclosure, it may refer to “a wafer itself” or “a stacked body of a wafer and certain layers or films formed on a surface of the wafer.” When the phrase “a surface of a wafer” is used in the present disclosure, it may refer to “a surface of a wafer itself” or “a surface of a certain layer and the like formed on a wafer.” When the expression “a certain layer is formed on a wafer” is used in the present disclosure, it may mean that “a certain layer is formed directly on a surface of a wafer itself” or that “a certain layer is formed on a layer and the like formed on a wafer.” When the term “substrate” is used in the present disclosure, it may be synonymous with the term “wafer.”

### (Wafer Loading)

After the boat 217 is charged with a plurality of wafers 200, as illustrated in FIG. 1, the boat 217 supporting the plurality of wafers 200 is lifted by the boat elevator 115 and is loaded into the process chamber 201.

### (Pressure Regulation and Temperature Regulation)

An inside of the process chamber 201, that is, a space where the wafers 200 are placed, is vacuum-exhausted (decompression-exhausted) by the vacuum pump 246 to reach a desired pressure (degree of vacuum). In this operation, the internal pressure of the process chamber 201 is measured by the pressure sensor 245, and the APC valve 244 is feedback-controlled based on the measured pressure information. The vacuum pump 246 is maintained in a constantly operating state at least until the processing of the wafers 200 is completed. Further, the wafers 200 in the process chamber 201 are heated by the heater 207 so as to reach a desired temperature. In this operation, a state of supplying electric power to the heater 207 is feedback-controlled based on the temperature information detected by the temperature sensor 263 such that a temperature distribution in the process chamber 201 becomes a desired temperature distribution. The heating of the inside of the process chamber 201 by the heater 207 continues at least until the processing of the wafers 200 is completed. Further, the rotation of the boat 217 and wafers 200 by the rotator 267 is started. The rotation of the boat 217 and wafers 200 by the rotator 267 continues at least until the processing of the wafers 200 is completed.

### (Film Formation)

Then, the following steps S11 to S14 are performed.

### [Supply of Precursor Gas, Step S11]

First, a precursor gas serving as the second reactant is supplied to the wafers 200 in the process chamber 201. Specifically, the valve 243a is opened to allow the precursor gas to flow through the gas supply pipe 232a. A flow rate of the precursor gas is regulated by the MFC 241a, supplied into the process chamber 201 via the nozzle 249a, and exhausted via the exhaust pipe 231. Simultaneously, the valve 243c is opened to allow an inert gas to flow through the gas supply pipe 232c. A flow rate of the inert gas is regulated by the MFC 241c, supplied, along with the precursor gas, into the process chamber 201, and exhausted via the exhaust pipe 231. Further, to prevent infiltration of the precursor gas into the nozzle 249b, the valve 243d is opened to allow the inert gas to flow through the gas supply pipe 232d. The inert gas is supplied into the process chamber 201 via the gas supply pipe 232d and nozzle 249b, and is exhausted via the exhaust pipe 231.

Processing conditions in step S11 are exemplified as follows:
Processing temperature: 400 to 750 degrees C., specifically 500 to 650 degrees C.;
Processing pressure (total pressure): 5 to 4,000 Pa, specifically 10 to 1,333 Pa;
Partial pressure of precursor gas: 1 to 3,000 Pa, specifically 5 to 1,500 Pa;
Supply flow rate of inert gas (total flow rate): 0 to 10,000 sccm, specifically 100 to 5,000 sccm; and
Processing time: 0.1 to 240 seconds, specifically 1 to 120 seconds.

In addition, the processing temperature may be substantially the same in any one of the following steps. Further, a processing temperature as used herein refers to a temperature of the wafer 200 or an internal temperature of the process chamber 201, and a processing pressure as used herein refers to an internal pressure of the process chamber 201. Further, a processing time refers to the time during which that processing continues. The same applies to the following description. In addition, notation of a numerical range such as “400 to 750 degrees C.” as used herein means that a lower limit value and an upper limit value are included in that range. Therefore, for example, “400 to 750 degrees C.” refers to “400 degrees C. or more and 750 degrees C. or less.” The same applies to other numerical ranges. In a case where a supply flow rate includes 0 sccm, it means a case where no substance (gas) is supplied. The same applies to the following description.

Under the above-described processing conditions, by supplying, for example, a chlorosilane-based gas as the precursor gas to the wafer 200, a silicon (Si)-containing layer containing chlorine (Cl) is formed on the surface of the wafer 200. The Si-containing layer containing Cl is formed on an outermost surface of the wafer 200 by physical adsorption or chemical adsorption of molecules of the chlorosilane-based gas, physical adsorption or chemical adsorption of molecules of a substance resulting from partial decomposition of the chlorosilane-based gas, or the like. The Si-containing layer containing Cl may be an adsorption layer (a physical adsorption layer or a chemical adsorption layer) of molecules of the chlorosilane-based gas or molecules of a substance resulting from partial decomposition of the chlorosilane-based gas. The Si-containing layer containing Cl is also simply referred to as a “Si-containing layer” herein. The Si-containing layer formed in this step is also simply referred to as a “first layer.”

A precursor gas containing a predetermined element may be used as the precursor gas. In particular, a precursor gas containing a predetermined element and a halogen element may be used as the precursor gas.

Examples of the halogen element may include Cl, fluorine (F), bromine (Br), iodine (I), and the like. One or more of these may be used as the halogen element.

Examples of the predetermined element may include semi-metal elements such as Si, boron (B), germanium (Ge), arsenic (As), antimony (Sb), and tellurium (Te), and metal elements such as titanium (Ti), aluminum (Al), tungsten (W), hafnium (Hf), zirconium (Zr), tantalum (Ta), molybdenum (Mo), ruthenium (Ru), and cobalt (Co).

Examples of the precursor gas containing the predetermined element may include a halosilane-based gas containing a halogen element and Si, an aminosilane-based gas containing an amino group and Si, and an inorganic silane-based gas containing Si.

Examples of the halosilane-based gas may include chlorosilane-based gases such as dichlorosilane (SiH₂Cl₂) gas, trichlorosilane (SiHCl₃) gas, tetrachlorosilane (SiCl₄) gas, and hexachlorodisilane (Si₂Cl₆) gas, fluorosilane-based gases such as tetrafluorosilane (SiF₄) gas and difluorosilane (SiH₂F₂) gas, bromosilane-based gases such as tetrabromosilane (SiBr₄) gas and dibromosilane (SiH₂Br₂) gas, iodosilane-based gases such as tetraiodosilane (SiI₄) gas and diiodosilane (SiH₂I₂) gas, and the like. One or more of these may be used as the halosilane-based gas.

Examples of aminosilane-based gases may include a tetrakis(dimethylamino)silane (Si[N(CH₃)₂]₄) gas, a tris(dimethylamino)silane (Si[N(CH₃)₂]₃H) gas, a bis(diethylamino)silane (Si[N(C₂H₅)₂]₂H₂) gas, a bis(tert-butylamino)silane (SiH₂[NH(C₄H₉)]₂) gas, and (diisopropylamino)silane (SiH₃[N(C₃H₇)₂]) gas, and the like. One or more of these may be used as the aminosilane-based gas.

Examples of the inorganic silane-based gas may include a monosilane (SiH₄) gas, disilane (Si₂H₆) gas, and trisilane (Si₃H₈) gas. One or more of these may be used as the inorganic silane-based gas.

Examples of the inert gas may include a nitrogen (N₂) gas or rare gases such as argon (Ar), helium (He), neon (Ne), and xenon (Xe). One or more of these gases may be used as the inert gas.

### [Purge, Step S12]

After the first layer containing the predetermined element is formed on at least a part of the wafer 200, the valve 243a is closed to stop the supply of the precursor gas. At this time, the APC valve 244 is fully opened, and the inside of the process chamber 201 is vacuum-exhausted by the vacuum pump 246 to remove any unreacted precursor gas remaining in the process chamber 201 and reaction products generated by the reaction between the precursor gas and the surface of the wafer 200 from the inside of the process chamber 201.

At this time, the valves 243c and 243d may be kept open to maintain the supply of the inert gas into the process chamber 201. The inert gas acts as a purge gas.

Herein, in contrast to a reaction (forward reaction) in which the precursor gas or a part of molecules of the precursor gas is adsorbed on the surface of the wafer 200, a reaction product which may react with the first layer formed on the surface of the wafer 200 to desorb the precursor gas or a part of molecules of the precursor gas adsorbed on the surface of the wafer 200 (reverse reaction) may specifically be referred to as a “reaction product A.”

When, for example, a halosilane-based gas is used as the precursor gas, the reaction product A may include a substance containing a halogen element contained in the precursor gas (for example, chlorine (Cl₂) or hydrogen chloride (HCl)). When, for example, an aminosilane-based gas is used as the precursor gas, the reaction product A may include a substance containing at least one selected from the group of carbon (C), nitrogen (N), and hydrogen (H) contained in the precursor gas (for example, a hydrogen (H₂) gas or a hydrocarbon compound). When, for example, an inorganic silane-based gas is used as the precursor gas, the reaction product A may include a substance containing H contained in the precursor gas (for example, a H₂ gas).

Processing conditions in step S12 are exemplified as follows:
Processing pressure (purge pressure) (total pressure): 0.1 to 1,330 Pa, specifically 1 to 400 Pa;
Supply flow rate of inert gas (total flow rate): 0 to 10,000 sccm, specifically 100 to 5,000 sccm; and
Processing time (purge time): 0.1 to 120 seconds, specifically 0.1 to 60 seconds. Other conditions may be the same as those in step S11.

### [Supply of Reaction Gas, Step S13]

Next, the reaction gas serving as the first reactant, which reacts with the first layer as the surface (also referred to as the “outermost surface”) of the wafer 200, is supplied at a first partial pressure to the wafer 200 within the process chamber 201. Specifically, the valve 243b is opened to allow the reaction gas to flow through the gas supply pipe 232b. A flow rate of the reaction gas is regulated by the MFC 241b, supplied into the process chamber 201 via the nozzle 249b, and exhausted via the exhaust pipe 231. At this time, the valve 243d is simultaneously opened to allow the inert gas to flow through the gas supply pipe 232d. A flow rate of the inert gas is regulated by the MFC 241d, supplied along with the reaction gas into the process chamber 201, and exhausted via the exhaust pipe 231. Further, to prevent infiltration of the reaction gas into the nozzle 249a, the valve 243c is opened to allow the inert gas to flow through the gas supply pipe 232c. The inert gas is supplied into the process chamber 201 via the gas supply pipe 232c and the nozzle 249a, and is exhausted via the exhaust pipe 231.

Processing conditions in step S13 are exemplified as follows:
Processing pressure (total pressure): 1,013 to 506,625 Pa, specifically 10,133 to 101,325 Pa;
Partial pressure of reaction gas (first partial pressure): 1,013 to 506,625 Pa, specifically 10,133 to 101,325 Pa;
Supply flow rate of inert gas (total flow rate): 0 to 5,000 sccm, specifically 50 to 2,500 sccm; and
Processing time: 1 to 180 seconds, specifically 10 to 60 seconds. Other processing conditions may be the same as those in step S11.

In addition, in this step, at least one selected from the group of the supply flow rate and the partial pressure of the inert gas is set to be lower than at least one selected from the group of the supply flow rate and the partial pressure of the inert gas in steps S11 and S12 described above and in step S14 described below. This may increase the partial pressure of the reaction gas supplied into the process chamber 201 in this step, thereby increasing a pressure difference between the partial pressure of the reaction gas and the partial pressure of the reaction product in the next step S14. Further, for example, in this step, the inert gas may not be substantially supplied into the process chamber 201, such that the partial pressure of the reaction gas supplied to the wafer 200 may be increased.

By supplying the reaction gas to the wafer 200 under the above-described conditions, at least a part of the first layer formed on the wafer 200 is modified. When, for example, a hydrogen nitride-based gas containing N and H is used as the reaction gas, at least a part of the first layer formed on the wafer 200 is nitrided, such that a silicon nitride layer (SiN layer) containing Si and N is formed on the outermost surface of the wafer 200. The SiN layer formed in this step is also simply referred to as a “second layer.”

For example, a nitriding agent may be used as the reaction gas. For example, a gas containing nitrogen (N) and hydrogen (H) may be used as the nitriding agent (nitriding gas). Examples of the gas containing N and H may include hydrogen nitride-based gases such as ammonia (NH₃) gas, diazen (N₂H₂) gas, hydrazine (N₂H₄) gas, and triazane (N₃H₅) gas. One or more of these may be used as the nitriding agent. In this step, when a nitriding agent is used as the reaction gas, the first layer is nitrided and modified into a nitride layer.

Further, for example, an oxidizing agent may be used as the reaction gas. For example, a gas containing oxygen (O) and hydrogen (H) may be used as the oxidizing agent (oxidizing gas). Examples of the gas containing O and H may include water vapor (H₂O gas), hydrogen peroxide (H₂O₂) gas, a mixed gas of hydrogen (H₂) gas and oxygen (O₂) gas, a mixed gas of H₂ gas and ozone (O₂) gas, and the like. Further, in addition to the gas containing O and H, for example, an oxygen (O)-containing gas may be used as the oxidizing agent. Examples of the O-containing gas may include O₂ gas, O₃ gas, nitrous oxide (N₂O) gas, nitrogen monoxide (NO) gas, nitrogen dioxide (NO₂) gas, carbon monoxide (CO) gas, carbon dioxide (CO₂) gas, and the like. Further, the gas containing O and H is a type of O-containing gas. One or more of these may be used as the oxidizing agent. In this step, when an oxidizing agent is used as the reaction gas, the first layer is oxidized and modified into an oxide layer.

The term “agent” as used herein includes at least one selected from the group of a gaseous substance and a liquid substance. The liquid substance includes a mist-like substance. In other words, the nitriding agent and oxidizing agent may include a gaseous substance, a liquid substance such as mist-like substance, or both.

### [Purge, Step S14]

After step S13 is completed, a residual gas within the process chamber 201 is removed. Specifically, after at least a part of the first layer on the wafer 200 is modified into the second layer, the valve 243b is closed to stop the supply of the reaction gas. At this time, the APC valve 244 is fully opened, and the interior of the process chamber 201 is vacuum-exhausted by the vacuum pump 246, thereby removing any unreacted reaction gas remaining in the process chamber 201 and reaction products generated by the reaction between the reaction gas and the surface of the wafer 200 (i.e., the surface of the first layer) from the interior of the process chamber 201. At this time, the valves 243c and 243d remain open to maintain the supply of the inert gas into the process chamber 201. The inert gas functions as a purge gas.

Herein, in contrast to a modification reaction (forward reaction) that occurs due to the reaction between the reaction gas and the surface of the wafer 200 (i.e., the surface of the first layer), a reaction product that reacts with the surface of the modified wafer 200 (i.e., the surface of the second layer) to return the second layer to the state thereof before the modification reaction (a reverse reaction) may specifically be referred to as a “reaction product B.”

Examples of the modification reaction as the forward reaction may include a nitriding reaction or an oxidizing reaction for the first layer, and a desorbing reaction to desorb impurities such as the halogen element or H from the first layer. On the other hand, examples of the reverse reaction may include a reaction to desorb N from the nitrided second layer, a reaction to desorb O from the oxidized second layer, and a reaction to reintroduce impurities into the second layer after impurity removal.

When, for example, a halosilane-based gas is used as the precursor gas and, for example, a hydrogen nitride-based gas is used as the reaction gas, the reaction product B may include a substance containing a halogen element and H (for example, hydrogen chloride (HCl)) and a substance containing H contained in the reaction gas (for example, a H₂ gas). When, for example, an aminosilane-based gas is used as the precursor gas and, for example, a hydrogen nitride-based gas is used as the reaction gas, the reaction product B may include a substance containing at least one selected from the group of C, N, and H (for example, a hydrogen (H₂) gas or a hydrocarbon compound). When, for example, an inorganic silane-based gas is used as the precursor gas and for example, a hydrogen nitride-based gas is used as the reaction gas, the reaction product B may include a substance containing H (for example, a H₂ gas).

In this step, the interior of the process chamber 201 is vacuum-exhausted by the vacuum pump 246 such that a partial pressure of the reaction product, that is, the reaction product B, which is generated by the reaction between the surface of the wafer 200 and the reaction gas present in the process chamber 201, is lowered to be equal to or less than a second partial pressure. Further, at this time, by supplying the inert gas as the purge gas into the process chamber 201, a reduction in the partial pressure of the reaction product B present in the process chamber 201 is further promoted.

Processing conditions in step S14 are exemplified as follows:
Processing pressure (purge pressure) (total pressure): 0.001 to 10 Pa, specifically 0.01 to 1 Pa;
Supply flow rate of inert gas (total flow rate): 0 to 10,000 sccm, specifically 100 to 5,000 sccm; and
Processing time: 1 to 240 seconds, specifically 2 to 180 seconds. Other processing conditions may be the same as those in step S11.

The broken line in FIG. 4 is an image diagram illustrating changes in the partial pressure of the reaction gas within the process chamber 201, and the one-dot dashed line in FIG. 4 is an image diagram illustrating changes in the partial pressure of the reaction product B within the process chamber 201. The reaction product B is generated by supplying the reaction gas in step S13 described above, and the reaction product B is removed in step S14. Here, a difference (also referred to as a “differential pressure”) between the partial pressure (first partial pressure) of the reaction gas during the supply of the reaction gas in step S13 described above and the partial pressure (second partial pressure) of the reaction product B within the process chamber 201 in step S14 is set to be equal to or greater than a predetermined value. Then, in step S14, a state where the partial pressure of the reaction product B within the process chamber 201 is equal to or less than the second partial pressure is maintained for a predetermined period (a period T2). Here, the predetermined value of the differential pressure may be set such that the partial pressure of the reaction product B within the process chamber 201 in step S14 relative to the partial pressure of the reaction product B within the process chamber 201 in step S13 corresponds to a first partial pressure ratio, which is a predetermined partial pressure ratio described below.

In addition, when a plurality of substances (e.g. HCl and H₂) are generated as the reaction product B, the “partial pressure of the reaction product B” in the present disclosure may sometimes refer to the partial pressure of each of the plurality of substances as the reaction product B. A sum of the partial pressures of the plurality of substances as the reaction product B may also be regarded as the partial pressure of the reaction product B.

Further, in the embodiments of the present disclosure, steps S13 and S14 described above may be performed such that a ratio of the second partial pressure, which is the partial pressure of the reaction product B in step S14, to the first partial pressure, which is the partial pressure of the reaction gas in step S13, is equal to or less than the first partial pressure ratio, which is the predetermined partial pressure ratio.

Further, steps S13 and S14 may be performed such that a ratio of the pressure (total pressure) within the process chamber 201 in step S14 to the first partial pressure, which is the partial pressure of the reaction gas in step S13, is equal to or lower than the first partial pressure ratio. Specifically, for example, steps S13 and S14 may be performed such that the ratio of the pressure (total pressure) within the process chamber 201 in step S14 to the partial pressure of the reaction gas in step S13 falls within the range of 10⁻⁷ to 10⁻⁴, specifically within the range of 10⁻⁶ to 10⁻⁵. In this configuration, when a plurality of reaction products B (for example, HCl and H₂) are present within the process chamber 201, steps S13 and S14 may be performed such that the ratio of the sum of the partial pressures of the plurality of reaction products B in step S14 to the partial pressure of the reaction gas in step S13 falls within the above-described ranges. In this way, it is easy to perform pressure regulation such that the ratio of the partial pressure of the reaction product within the process chamber 201 in step S14 to the partial pressure of the reaction gas in step S13 is equal to or less than the first partial pressure ratio, without measuring the partial pressure of the reaction product.

In this step, the partial pressure of the reaction product B present within the process chamber 201 may be lowered to the second partial pressure by increasing a degree of opening a valve (such as the APC valve 244) on an exhaust path. Further, in this step, the partial pressure of the reaction product B present within the process chamber 201 may be lowered to the second partial pressure by increasing an exhaust speed of an exhauster (such as the vacuum pump 246). Further, in this step, the partial pressure of the reaction product B present within the process chamber 201 may be lowered to the second partial pressure by increasing the partial pressure of the inert gas supplied into the process chamber 201.

Further, the difference between the first partial pressure and the second partial pressure may be set to be equal to or greater than a predetermined value by increasing the partial pressure (first partial pressure) of the reaction gas in step S13. Similarly, the ratio of the second partial pressure to the first partial pressure may be set to be equal to or less than the first partial pressure ratio by increasing the first partial pressure in step S13.

Here, when a gas containing N and H (for example, a hydrogen nitride-based gas such as NH₃ gas) is used as the reaction gas and a substance containing a halogen element (for example, a compound containing H and a halogen element such as HCl) is generated as the reaction product B (hereinafter referred to as a “first combination”), steps S13 and S14 are performed such that the ratio of the second partial pressure to the first partial pressure falls within the range of 10⁻⁷ to 10⁻⁴, specifically within the range of 10⁻⁶ to 10⁻⁵. That is, in this case, the first partial pressure ratio is set to a value within these ranges. In addition, the reaction product B in this specific example may also specifically be referred to as a “first reaction product B.” In a case where the ratio is less than 10⁻⁷, it may be difficult to provide a reaction gas supply system and an exhaust system configured to be capable of achieving such a ratio. In a case where the ratio is less than 10⁻⁶, the first partial pressure may become too high, making it difficult to supply the reaction gas to the wafer 200 in an appropriate state. By setting the ratio to be equal to or greater than 10⁻⁶, it is easy to achieve the ratio by controlling the second partial pressure even when the first partial pressure is equal to or less than atmospheric pressure. In a case where the ratio exceeds 10⁻⁵, it may be difficult to make a value of formation free energy (ΔGb) (to be described later) in the modification reaction that occurs in steps S13 and S14 negative, depending on others conditions such as the processing temperature. By setting the ratio to be equal to or less than 10⁻⁵, it becomes easy to make the value of ΔGb negative. In a case where the ratio exceeds 10⁻⁴, it may be difficult to make the value of ΔGb negative regardless of other conditions.

Further, when a gas containing N and H (for example, a hydrogen nitride-based gas such as NH₃ gas) is used as the reaction gas and a substance containing H (for example, a substance composed of H such as H₂) is generated as the reaction product B (hereinafter referred to as a “second combination”), steps S13 and S14 are performed such that the ratio of the second partial pressure to the first partial pressure falls within the range of 10⁻⁷ to 10⁻³, specifically within the range of 10⁻⁶ to 10⁻⁴. That is, in this case, the first partial pressure ratio is set to a value within these ranges. In a case where the ratio is less than 10⁻⁷, it may be difficult to provide the reaction gas supply system and the exhaust system configured to be capable of achieving such a ratio. In a case where the ratio is less than 10⁻⁶, the first partial pressure may become too high, making it difficult to supply the reaction gas to the wafer 200 in an appropriate state. By setting the ratio to be equal to or greater than 10⁻⁶, it becomes easy to achieve the ratio by controlling the second partial pressure even when the first partial pressure is equal to or less than atmospheric pressure. In a case where the ratio exceeds 10⁻⁴, it may be difficult to make the value of ΔGb negative, depending on other conditions such as the processing temperature. By setting the ratio to be equal or less than 10⁻⁴, it becomes easy to make the value of ΔGb negative. In a case where the ratio exceeds 10⁻³, it may be difficult to make the value of ΔGb negative regardless of other conditions.

For distinction from the first reaction product B in the example of the first combination described above, the reaction product B in the example of the second combination may specifically be referred to as a “second reaction product B.” The first reaction product B and the second reaction product B are different substances. Further, for distinction from the first partial pressure ratio corresponding to the first reaction product B described above, the first partial pressure ratio in the example of the second combination may specifically be referred to as a “second partial pressure ratio” (or a “second predetermined partial pressure ratio”). The first partial pressure ratio and the second partial pressure ratio may be different values. Further, for distinction from the second partial pressure corresponding to the first reaction product B described above, the second partial pressure in this specific example may specifically be referred to as a “third partial pressure.” The second partial pressure and the third partial pressure may be set to different values corresponding to the different first and second partial pressure ratios, respectively. For example, in this case, the third partial pressure may be set to be 10 times the second partial pressure.

In other words, the appropriate value set as the first partial pressure ratio, which is the ratio of the second partial pressure or third partial pressure to the first partial pressure in steps S13 and S14, may vary depending on combinations of the reaction gas and the reaction product B generated by supplying the reaction gas, and may be set depending on the combinations. For example, the partial pressures of the reaction gas and the reaction product B in each step are set to achieve an optimal pressure ratio depending on the combinations of the reaction gas and the reaction product B. This makes it possible to set a lower partial pressure of the reaction gas in step S13 depending on a type of gas. Further, a degree of vacuum within the process chamber 201 in step S14 may be lowered depending on the type of gas. For example, in a case where the partial pressure ratio of HCl as the reaction product B present within the process chamber 201 is equal to or less than 10⁻⁵, it is sufficient if the partial pressure ratio of H₂ satisfies the condition of 10⁻⁴ or less.

According to verification by the present disclosers, it is confirmed that as the difference between the partial pressure of the reaction gas in step S13 (first partial pressure) and the partial pressure of the reaction product B remaining within the process chamber 201 (second partial pressure) is increased, the modification reactions such as nitrification or oxidation of the film is promoted. Similarly, it is confirmed that as the ratio of the second partial pressure to the first partial pressure is increased, these modification reactions are promoted.

In the present disclosure, by setting the differential pressure between the first partial pressure and the second partial pressure to be equal to or greater than the above-described predetermined value, or by setting the ratio of the second partial pressure to the first partial pressure to be equal to or less than the above-described predetermined partial pressure ratio (i.e., the first partial pressure ratio), it is possible to make the value of formation free energy (ΔGb) in the reaction between the first layer and the reaction gas negative. Providing a condition under which the value of ΔGb is negative may bring about a state where an exothermic reaction occurs in the reaction between the first layer and the reaction gas.

In other words, the first partial pressure ratio, which is the predetermined partial pressure ratio in the embodiments of the present disclosure, may be set to a ratio value at which the value of ΔGb is negative. In other words, the first partial pressure ratio may be a ratio at which an exothermic reaction occurs during transition from the state before the reaction between the first layer and the reaction gas in step S13 to the state in step S14. In this way, by setting the first partial pressure ratio to a ratio at which an exothermic reaction occurs during the state transition, the reaction caused by the supply of the reaction gas (i.e., the forward reaction described above) may be further promoted without increasing the processing temperature.

Here, by the supply of the reaction gas, atomic bonds on the surface of the wafer 200 change from the initial state to the final state. FIG. 5A is an image diagram of the surface of the wafer 200 (i.e., the surface of the first layer) in the initial state before the supply of the reaction gas, and FIG. 5B is an image diagram of the surface of the wafer 200 (i.e., the surface of the second layer) in the final state after the supply of the reaction gas. FIG. 5A illustrates a state where a NH₃ gas as the reaction gas is supplied to a layer containing Si and Cl as the first layer, and FIG. 5B illustrates a state where a layer (that is, the second layer) containing Si and N as the second layer is formed and HCl is present as the reaction product B. In the process of changes in atomic bonds from the initial state in FIG. 5A to the final state in FIG. 5B, the reaction system between the first layer and the reaction gas transitions to a transition state which the highest energy state among the energy states of the reaction system. The difference between the energy level (eV) in this transition state and the energy level (eV) in the initial state (before reaction) is referred to as an “activation Gibbs energy (ΔGa).” Further, the difference between the energy level (eV) in the final state (after reaction) and the energy level (eV) in the initial state (before reaction) is referred to as the “formation free energy (ΔGb).”

When ΔGb is positive, i.e. ΔGb>0, probability of a state transition (i.e., reverse reaction) from the final state to the initial state tends to become relatively high between the reaction product B such as HCl or H₂ and the second layer. That is, the modification reaction from the first layer to the second layer by the reaction gas is unlikely to proceed, which may lead to a reduction in efficiency of the modification reaction such as nitrification or oxidation, or may result in insufficient modification.

In contrast, when ΔGb is negative, i.e., ΔGb<0, the probability of the above-described reverse reaction tends to decrease relatively. That is, the modification reaction (forward reaction) from the first layer to the second layer by the reaction gas is more likely to proceed, which may improve the efficiency of the modification reaction, and may prevent insufficient modification of the first layer. More specifically, promoting the modification reaction in this way may improve a film formation rate and may improve a step coverage.

Table 1 below summarizes simulation results in which the partial pressure of NH₃ as the reaction gas (first partial pressure) in step S13 and the partial pressure of HCl as the reaction product B (second partial pressure) in step S14 are set under different conditions, and ΔGa and A Gb are calculated for each condition. In this simulation, the surface of the wafer 200 in the initial state in step S13 is made as illustrated in FIG. 5A.

TABLE 1

| | | Partial | | |
|---|---|---|---|---|
| | Partial pressure | pressure of | | |
| Sample | of reaction gas | reaction | | |
| number | (Pa) | product (Pa) | Δ Ga (eV) | Δ Gb(eV) |
| Sample 1 | 101325 | 100 | 2.48 | 0.17 |
| Sample 2 | 101325 | 1 | 2.48 | −0.19 |
| Sample 3 | 100 | 100 | 3.03 | 0.72 |
| Sample 4 | 100 | 1 | 3.03 | 0.36 |

In Sample 1, when the first partial pressure is set to 101,325 Pa and the second partial pressure is set to 100 Pa, ΔGa is 2.48 eV and ΔGb is 0.17 eV.
In Sample 2, when the first partial pressure is set to 101,325 Pa and the second partial pressure is set to 1 Pa, ΔGa is 2.48 eV and ΔGb is-0.19 eV.
In Sample 3, when the first partial pressure is set to 100 Pa and the second partial pressure is set to 100 Pa, ΔGa is 3.03 eV and ΔGb is 0.72 eV.
In Sample 4, when the first partial pressure is set to 100 Pa and the second partial pressure is set to 1 Pa, ΔGa is 3.03 eV and ΔGb is 0.36 eV.

From Sample 2 in Table 1, it can be confirmed that the formation free energy (ΔGb) may be made negative by increasing the first partial pressure to, for example, approximately atmospheric pressure and reducing the second partial pressure to approximately 1 Pa. In other words, according to this simulation, it can be seen that ΔGb may be made negative by setting the ratio of the partial pressure of the reaction product B in step S14 to the partial pressure of the reaction gas in step S13 to be equal to or less than 10⁻⁵ (i.e., by setting the first partial pressure ratio to 10⁻⁵). In other words, ΔGb may be made negative by setting the partial pressure of the reaction gas in step S13 to be greater than, by the five orders of magnitude or more (i.e., 100,000 times or more), the partial pressure of the reaction product B in step S14. In addition, since the internal pressure (total pressure) of the process chamber 201 is equal to or greater than the partial pressure of the gas present therein, ΔGb may also be made negative by setting the ratio of the internal pressure of the process chamber 201 after depressurization in step S14 (i.e., the processing pressure in step S14) to the partial pressure of the reaction gas in step S13 to be equal to or less than 10⁻⁵.

When using a H-containing gas such as NH₃ gas as the reaction gas, a compound gas containing H different from the reaction gas (for example, a compound containing a halogen element and H such as HCl) or a H₂ gas is generated as the reaction product. When both the reaction gas and the reaction product contain H, the value of ΔGb in the reaction between the first layer and the reaction gas tends to be positive (i.e., the reverse reaction tends to occur easily). Therefore, in such a case, controlling the ratio of the second partial pressure to the first partial pressure to be equal to or less than the first partial pressure ratio (i.e., to make the value of ΔGb negative) as in the embodiments of the present disclosure is particularly effective in promoting the modification reaction.

In addition, in this step, as illustrated in FIG. 4, a state where the partial pressure of the reaction product within the process chamber 201 is equal to or less than the second partial pressure is maintained for a predetermined period (period T2). In this step, the period T2 is set to be longer than a period T1 until a state where the partial pressure of the reaction product B within the process chamber 201 becomes equal to or less than the second partial pressure is reached after the supply of the reaction gas in step S13 is stopped. By shortening the period T1 during which the reverse reaction is likely to occur with respect to the modification reaction, occurrence of the reverse reaction in this step may be prevented, and the modification reaction may be promoted.

Further, an execution time of this step is made longer than an execution time of step S12. Thus, in this step, it is possible to sufficiently lower the partial pressure of the reaction product, and it becomes easier to lower the partial pressure of the reaction product to the first partial pressure ratio.

### (Performed Predetermined Number of Times)

A cycle including the above-described steps S11 to S14 is performed a predetermined number of times (n times, where n is an integer of 1 or 2 or more). Thus, a film containing a predetermined element with a predetermined thickness is formed on the wafer 200. For example, when a gas containing Si as the predetermined element is used as the precursor gas and a nitriding agent is used as the reaction gas, a silicon nitride film (SiN film) is formed as the film containing the predetermined element. Further, for example, when a gas containing Si as the predetermined element is used as the precursor gas and an oxidizing agent is used as the reaction gas, a silicon oxide film (SiO film) is formed as the film containing the predetermined element.

(after Purge and Returning to Atmospheric Pressure)

The inert gas is supplied into the process chamber 201 via each of the gas supply pipes 232c and 232d, and is exhausted via the exhaust pipe 231. Thus, the interior of the process chamber 201 is purged, and thereafter, the internal atmosphere of the process chamber 201 is replaced with an inert gas, and the internal pressure of the process chamber 201 is returned to atmospheric pressure.

### (Boat Unloading and Wafer Discharge)

The seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). The processed wafers 200 are unloaded from the boat 217.

### Other Embodiments of Present Disclosure

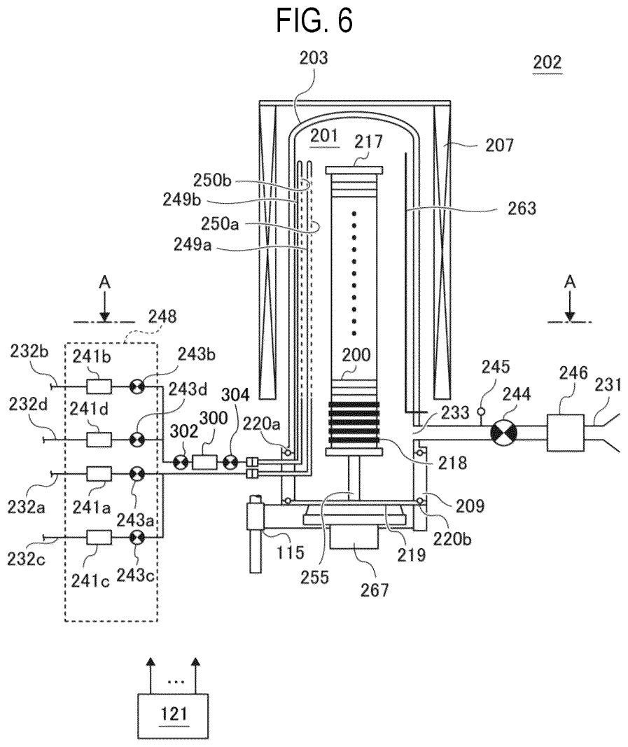

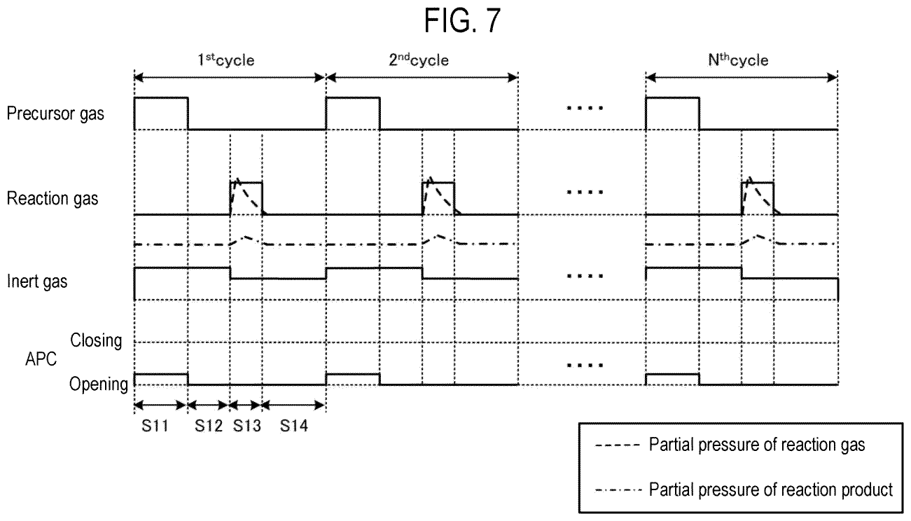

Next, other embodiments of the above-described substrate processing apparatus will be described with reference to FIGS. 6 and 7. In addition, in the substrate processing apparatus of the embodiments of the present disclosure, the same reference numerals are given to components that are substantially the same as those described in FIG. 1, and the description thereof is omitted.

In the embodiments of the present disclosure, as illustrated in FIG. 6, at the downstream side of the valve 243b of the gas supply pipe 232b and at the downstream side of a junction between the gas supply pipe 232b and the gas supply pipe 232d, a valve 302, a tank 300 serving as a storage configured to store a gas, and a valve 304 are installed in this order from the upstream side of gas flow. That is, the tank 300 and valves 302 and 304 are installed on the supply lines of the reaction gas and the inert gas. The reaction gas supply system (also referred to as a “first reactant supply system”) in the embodiments is mainly constituted by the gas supply pipe 232b, MFC 241b, valve 243b, valve 302, tank 300, and valve 304. The inert gas supply system connected to the reaction gas supply system may also be included in the reaction gas supply system. In addition, the storage is not limited to being constituted by the tank 300, but may also be constituted by the gas supply pipe 232b constituting a section between the valve 302 and the valve 304.

The tank 300 is temporarily charged with the reaction gas supplied from the gas supply pipe 232b and the inert gas supplied from the gas supply pipe 232d by opening or closing the valve 302 on its upstream side and the valve 304 on its downstream side. The reaction gas and the inert gas are mixed within the tank 300, and the reaction gas is diluted with the inert gas. At this time, a partial pressure of the reaction gas within the tank 300 is increased (i.e., pressurized). Then, the reaction gas, which is charged into the tank 300, increased in the partial pressure, and diluted with the inert gas, is supplied to the wafer 200 in a large quantity at once.

In the embodiments of the present disclosure, during the supply of reaction gas in step S13 of the substrate processing of the above-described embodiments, the reaction gas pressurized within the tank 300 is supplied to the wafer 200 within the process chamber 201 by using the tank 300 and valves 302 and 304 at substantially the same processing temperature.

Specifically, during the supply of reaction gas in step S13, by closing the valve 304 and opening the valves 243b, 243d, and 302 in advance, the tank 300 is charged with the reaction gas and the inert gas, the flow rates of which are regulated by the MFCs 241b and 241d, respectively. Then, by opening the valve 304, a mixture of the inert gas and the reaction gas, which is charged into the tank 300 and increased in the partial pressure, is supplied to the wafer 200 in large quantity at once. By supplying the reaction gas with an increased partial pressure to the wafer 200 in a large quantity at once, the first partial pressure may be increased, and the differential pressure relative to the partial pressure of the reaction product (second partial pressure) in the next step S14 may be increased. Further, by supplying the reaction gas with the increased partial pressure to the wafer 200 in a large quantity at once, the first partial pressure may be increased, and the ratio of the second partial pressure to the first partial pressure may be reduced.

In these embodiments as well, the same effects as in the above-described embodiments may be obtained. Further, in the embodiments as well, by increasing the partial pressure of the reaction gas in step S13, it becomes easier to reduce the ratio of the partial pressure of the reaction product in the next step S14 to the partial pressure of the reaction gas. In other words, in the embodiments, it becomes easier to make the ratio of the second partial pressure to the first partial pressure equal to or less than the first partial pressure ratio. Therefore, the modification reaction such as nitridation or oxidation may be promoted, and as a result, a film formation rate may be improved and a step coverage may be improved.

The embodiments of the present disclosure are specifically described above. However, the present disclosure is not limited to the above-described embodiments, and may be changed in various ways without departing from the gist of the present disclosure.

Further, the supply of precursor gas in step S11 and the purge in step S12 described above may also be applied in the same way as the supply of reaction gas in step S13 and the purge in step S14 described above. That is, in steps S11 and S12, the same effects as the above-described embodiments may be obtained by setting the ratio of the partial pressure of the reaction product (i.e., the reaction product A) in the next step S12 to the partial pressure of the precursor gas in step S11 to be equal to or less than a predetermined partial pressure ratio (may also be referred to as a “third partial pressure ratio”). For example, in step S11, when a halosilane-based gas (for example, a chlorosilane-based gas) is used as the precursor gas, a compound containing a halogen element may be generated as the reaction product A. In this case, steps S11 and S12 are performed such that the ratio of the partial pressure of the reaction product A (for example, Cl₂ or HCl) in step S12 to the partial pressure of the precursor gas in step S11 is equal to or less than the third partial pressure ratio. Similar to the first partial pressure ratio, the third partial pressure ratio is the ratio at which ΔGb in the reaction system between the surface of the wafer 200 and the precursor gas becomes negative and an exothermic reaction occurs.

In the above-described embodiments, the case of forming a Si-containing film as a film containing a predetermined element is described as an example, but the present disclosure is not limited thereto. Examples of the film containing the predetermined element may include a film containing a metal element such as a titanium film (Ti film), a titanium nitride film (TiN film), a titanium oxide film (TiO film), a tungsten film (W film), a tungsten nitride film (WN film), a tungsten oxide film (WO film), a hafnium nitride film (HfN film), a hafnium oxide film (HfO film), a zirconium nitride film (ZrN film), a zirconium oxide film (ZrO film), a tantalum nitride film (TaN film), a tantalum oxide film (TaO film), a molybdenum film (Mo film), a molybdenum nitride film (MoN film), a molybdenum oxide film (MoO film), an aluminum film (Al film), an aluminum nitride film (AlN film), an aluminum oxide film (AlO film), a ruthenium film (Ru film), or a cobalt film (Co film). In these cases as well, the same effects as in the above-described embodiments may be obtained.

In the above-described embodiments, the example of forming a film by using a batch-type substrate processing apparatus configured to process a plurality of substrates at once is described. The present disclosure is not limited to the above-described embodiments, and for example, may be suitably applied even when forming a film by using a single-wafer-type substrate processing apparatus configured to process one or several substrates at once. Further, in the above-described embodiments, the example of forming a film by using a substrate processing apparatus including a hot-wall-type process furnace is described. The present disclosure is not limited to the above-described embodiments, and may be suitably applied to the case of forming a film by using a substrate processing apparatus including a cold-wall-type process furnace.

Even when using such a substrate processing apparatus, it is possible to perform each process by using the same processing procedures and processing conditions as in the above-described embodiments, and to achieve the same effects as in the above-described embodiments.

The above-described embodiments may be used in combination as appropriate. For example, the processing procedures and processing conditions at this time may be the same as the processing procedures and processing conditions in the above-described embodiments.

According to the present disclosure, it is possible to improve a film formation efficiency in a film formation including supplying a reactant to a substrate.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
forming a film on the substrate by performing a cycle a predetermined number of times, the cycle including:
(a) supplying a first reactant which reacts with a surface of the substrate to the substrate at a first partial pressure; and
(b) after (a), exhausting a process space in which the substrate is processed such that a partial pressure of a reaction product, which is generated by a reaction between the surface of the substrate and the first reactant and present in the process space, becomes a second partial pressure,
wherein (a) and (b) are performed such that the first partial pressure and the second partial pressure are set, respectively, to make a ratio of the second partial pressure to the first partial pressure be equal to or less than a predetermined partial pressure ratio.

2. The method of claim 1, wherein the predetermined partial pressure ratio is a ratio at which an exothermic reaction occurs in (b).

3. The method of claim 1, wherein the predetermined partial pressure ratio is a ratio at which a formation free energy (ΔG) becomes negative, the formation free energy being a difference obtained by subtracting an energy level of a reaction system before the reaction between the surface of the substrate and the first reactant from an energy level of the reaction system after the reaction between the surface of the substrate and the first reactant.

4. The method of claim 1, wherein the predetermined partial pressure ratio is set according to a combination of the first reactant and the reaction product.

5. The method of claim 1, wherein in (b), the process space is exhausted such that a partial pressure of a second reaction product generated by the reaction between the surface of the substrate and the first reactant, which is present in the process space and different from the reaction product, becomes a third partial pressure, and
wherein (a) and (b) are performed such that the first partial pressure and the third partial pressure are set, respectively, to make a ratio of the third partial pressure to the first partial pressure be equal to or less than a second predetermined partial pressure ratio.

6. The method of claim 1, wherein the first reactant includes a hydrogen-containing gas, and
wherein the reaction product is a hydrogen-containing compound different from the first reactant.

7. The method of claim 1, wherein the cycle further includes (c) before (a), supplying a second reactant containing a halogen element to the substrate,
wherein in (a), a hydrogen-containing gas as the first reactant is supplied to the substrate, and
wherein the reaction product is a compound of the halogen element and hydrogen, or a hydrogen gas.

8. The method of claim 7, wherein the first reactant includes a hydrogen nitride gas.

9. The method of claim 8, wherein the reaction product is the compound of the halogen element and hydrogen, and
wherein the predetermined partial pressure ratio is equal to or less than 10⁻⁵.

10. The method of claim 8, wherein the reaction product is the hydrogen gas, and wherein the predetermined partial pressure ratio is equal to or less than 10⁻⁴.

11. The method of claim 7, wherein the second reactant further contains a predetermined element which is a metal element or a semi-metal element, and
wherein the film is a film containing the predetermined element.

12. The method of claim 1, wherein in (b), the partial pressure of the reaction product present in the process space is lowered to the second partial pressure by supplying an inert gas into the process space.

13. The method of claim 1, wherein in (b), the process space is exhausted such that a ratio of an internal pressure of the process space in (b) to the first partial pressure is equal to or less than the predetermined partial pressure ratio.

14. The method of claim 1, wherein in (b), a state where the partial pressure of the reaction product in the process space is the second partial pressure is maintained for a predetermined period.

15. The method of claim 14, wherein the predetermined period is longer than a period after starting (b) until the partial pressure of the reaction product in the process space reaches the second partial pressure.

16. The method of claim 7, wherein the cycle further includes (d), between (c) and (a), exhausting the process space while the act of supplying the second reactant is stopped, and
wherein an execution time of (b) is longer than an execution time of (d).

17. The method of claim 1, wherein (a) includes:
(a-1) charging a storage with the first reactant to increase a partial pressure of the first reactant in the storage; and
(a-2) after (a-1), supplying the first reactant, which is charged in the storage, to the substrate.

18. A method of manufacturing a semiconductor device comprising the method of claim 1.

19. A non-transitory computer-readable recording medium storing a program that causes, by a computer, a substrate processing apparatus to perform a process comprising:
forming a film on a substrate by performing a cycle a predetermined number of times, the cycle including:
(a) supplying a first reactant which reacts with a surface of the substrate to the substrate at a first partial pressure; and
(b) after (a), exhausting a process space in which the substrate is processed such that a partial pressure of a reaction product, which is generated by a reaction between the surface of the substrate and the first reactant and present in the process space, becomes a second partial pressure,
wherein (a) and (b) are performed such that the first partial pressure and the second partial pressure are set, respectively, to make a ratio of the second partial pressure to the first partial pressure be equal to or less than a predetermined partial pressure ratio.

20. A substrate processing apparatus comprising:
a first reactant supply system configured to supply a first reactant which reacts with a surface of a substrate to the substrate;
an exhaust system configured to exhaust a process space in which the substrate is processed; and
a controller configured to be capable of controlling the first reactant supply system and the exhaust system so as to perform a process comprising:
forming a film on the substrate by performing a cycle a predetermined number of times, the cycle including:
(a) supplying the first reactant to the substrate at a first partial pressure; and
(b) after (a), exhausting the process space in which the substrate is processed such that a partial pressure of a reaction product, which is generated by a reaction between the surface of the substrate and the first reactant and present in the process space, becomes a second partial pressure,
wherein (a) and (b) are performed such that the first partial pressure and the second partial pressure are set, respectively, to make a ratio of the second partial pressure to the first partial pressure be equal to or less than a predetermined partial pressure ratio.
